(19) United States
(12) Patent Application Publication
(10) Pub. No.: US 2017/0275779 A1
(43) Pub. Date: Sep. 28, 2017

(54) SILICON CARBIDE EPITAXIAL SUBSTRATE AND METHOD FOR MANUFACTURING SILICON CARBIDE SEMICONDUCTOR DEVICE

(71) Applicant: Sumitomo Electric Industries, Ltd., Osaka-shi (JP)

(72) Inventors: Taro Nishiguchi, Itami-shi (JP); Kenji Hiratsuka, Itami-shi (JP)

(21) Appl. No.: 15/503,919

(22) PCT Filed: Jul. 4, 2016
(86) PCT No.: PCT/JP2016/069801

§ 371 Date: Feb. 14, 2017

(30) Foreign Application Priority Data
Oct. 7, 2015 (JP) 2015-199565

(51) Int. Cl. C30B 29/36; H01L 21/02; H01L 21/04; C30B 25/20

(52) U.S. Cl. CPC C30B 29/36; C30B 25/20; H01L 21/0262; H01L 21/02529; H01L 21/0243; H01L 21/02433; H01L 21/047

(57) ABSTRACT

The silicon carbide layer includes a second main surface opposite to a surface in contact with the silicon carbide single crystal substrate. The second main surface corresponds to a plane inclined relative to a {0001} plane in an off direction. The second main surface has a maximum diameter of not less than 100 mm. The second main surface has an outer circumferential region and a central region, the central region being surrounded by the outer circumferential region. The central region is provided with a first dislocation array of first half loops along a straight line perpendicular to the off direction. Each of the first half loops includes a pair of threading edge dislocations exposed at the second main surface. An area density of the first dislocation array at the central region is not more than 10/cm².

### TECHNICAL FIELD

The present disclosure relates to a silicon carbide epitaxial substrate and a method for manufacturing a silicon carbide semiconductor device. The present application claims a priority based on Japanese Patent Application No. 2015-199565 filed on Oct. 7, 2015, the entire content of which is incorporated herein by reference.

### BACKGROUND ART

WO2009/035095 (Patent Document 1) discloses an epitaxial substrate having a dislocation array generated during epitaxial growth.

### CITATION LIST

### Patent Document

PTD 1: WO2009/035095

### SUMMARY OF INVENTION

A silicon carbide epitaxial substrate according to the present disclosure includes a silicon carbide single crystal substrate and a silicon carbide layer. The silicon carbide single crystal substrate has a first main surface. The silicon carbide layer is on the first main surface. The silicon carbide layer includes a second main surface opposite to a surface in contact with the silicon carbide single crystal substrate. The second main surface corresponds to a plane inclined relative to a {0001} plane in an off direction. The second main surface has a maximum diameter of not less than 100 mm. The second main surface has an outer circumferential region and a central region, the outer circumferential region being within 3 mm from an outer edge of the second main surface, the central region being surrounded by the outer circumferential region. The central region is provided with a first dislocation array of first half loops along a straight line perpendicular to the off direction. Each of the first half loops includes a pair of threading edge dislocations exposed at the second main surface. An area density of the first dislocation array at the central region is not more than 10/cm².

A silicon carbide epitaxial substrate according to the present disclosure includes a silicon carbide single crystal substrate and a silicon carbide layer. The silicon carbide single crystal substrate has a first main surface. The silicon carbide layer is on the first main surface. The silicon carbide layer includes a second main surface opposite to a surface in contact with the silicon carbide single crystal substrate. The second main surface corresponds to a plane inclined by not more than 4° relative to a (0001) plane in a <11-20> direction. The second main surface has a maximum diameter of not less than 150 mm. The second main surface has an outer circumferential region and a central region, the outer circumferential region being within 3 mm from an outer edge of the second main surface, the central region being surrounded by the outer circumferential region. The central region is provided with a dislocation array of half loops along a straight line perpendicular to the <11-20> direction. Each of the half loops includes a pair of threading edge dislocations exposed at the second main surface. An area density of the dislocation array at the central region is not more than 10/cm².

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view taken along an II-II line of FIG. 1.

FIG. 3 is a schematic perspective view in a region III of FIG. 1.

FIG. 4 is a schematic plan view in region III of FIG. 1.

FIG. 5 is a schematic cross sectional view in region III of FIG. 1.

FIG. 6 is a schematic perspective view in a region VI of FIG. 1.

FIG. 7 is a schematic plan view in region VI of FIG. 1.

FIG. 8 is a schematic cross sectional view in region VI of FIG. 1.

FIG. 9 is a partial schematic cross sectional view showing a configuration of a manufacturing apparatus for the silicon carbide epitaxial substrate according to the present embodiment.

FIG. 10 is a schematic plan view showing a first step of a method for manufacturing the silicon carbide epitaxial substrate according to the present embodiment.

FIG. 11 is a schematic cross sectional view taken along a XI-XI line of FIG. 10.

FIG. 12 shows a relation between temperature and time in the method for manufacturing the silicon carbide epitaxial substrate according to the present embodiment.

FIG. 13 is a schematic perspective view showing a configuration of a basal plane dislocation on a region XIII of FIG. 10 at a zeroth time in a growing step.

FIG. 14 is a schematic perspective view showing the configuration of the basal plane dislocation on region XIII of FIG. 10 at a first time in the growing step.

FIG. 15 is a schematic perspective view showing the configuration of the basal plane dislocation on region XIII of FIG. 10 at a third time in the growing step.

FIG. 16 is a schematic perspective view showing configurations of the basal plane dislocation and first half loops on region XIII of FIG. 10 in the cooling step.

FIG. 17 is a schematic perspective view showing a configuration of a basal plane dislocation on a region XVII of FIG. 10 at the zeroth time in the growing step.

FIG. 18 is a schematic perspective view showing configurations of the basal plane dislocation and a second half loop on region XVII of FIG. 10 at the first time in the growing step.

FIG. 19 is a schematic perspective view showing the configurations of the basal plane dislocation and the second half loops on region XVII of FIG. 10 at a second time in the growing step.

FIG. 20 shows a relation between pressure and time in a method for manufacturing the silicon carbide epitaxial substrate according to the present embodiment.

FIG. 21 is a flowchart showing the method for manufacturing the silicon carbide semiconductor device according to the present embodiment.

FIG. 22 is a schematic cross sectional view showing a first step of the method for manufacturing the silicon carbide semiconductor device according to the present embodiment.

FIG. 23 is a schematic cross sectional view showing a second step of the method for manufacturing the silicon carbide semiconductor device according to the present embodiment.

FIG. 24 is a schematic cross sectional view showing a third step of the method for manufacturing the silicon carbide semiconductor device according to the present embodiment.

### DESCRIPTION OF EMBODIMENTS

### Technical Problem

An object of the present disclosure is to provide a silicon carbide epitaxial substrate and a method for manufacturing a silicon carbide semiconductor device, by each of which a dislocation array of half loops along a straight line perpendicular to an off direction can be reduced.

### Advantageous Effect of Present Disclosure

According to the present disclosure, there can be provided a silicon carbide epitaxial substrate and a method for manufacturing a silicon carbide semiconductor device, by each of which a dislocation array of half loops along a straight line perpendicular to an off direction can be reduced.

### Overview of Embodiment of Present Disclosure

(1) A silicon carbide epitaxial substrate 100 according to the present disclosure includes a silicon carbide single crystal substrate 10 and a silicon carbide layer 20. Silicon carbide single crystal substrate 10 has a first main surface 11. Silicon carbide layer 20 is on first main surface 11. Silicon carbide layer 20 includes a second main surface 30 opposite to a surface 14 in contact with silicon carbide single crystal substrate 10. Second main surface 30 corresponds to a plane inclined relative to a {0001} plane in an off direction. Second main surface 30 has a maximum diameter 111 of not less than 100 mm. Second main surface 30 has an outer circumferential region 52 and a central region 53, outer circumferential region 52 being within 3 mm from an outer edge 54 of second main surface 30, central region 53 being surrounded by outer circumferential region 52. Central region 53 is provided with a first dislocation array 2 of first half loops 1 along a straight line perpendicular to the off direction. Each of first half loops 1 includes a pair of threading edge dislocations exposed at second main surface 30. An area density of first dislocation array 2 at central region 53 is not more than 10/cm².

Normally, a dislocation array of threading edge dislocations exists in a silicon carbide epitaxial substrate. Such a dislocation array causes decreased breakdown voltage of a semiconductor device, increased leakage current, decreased reliability of the semiconductor device, and the like. Accordingly, it is required to reduce dislocation arrays. As a result of diligent study on a method for reducing the dislocation arrays of the threading edge dislocations, the inventors have obtained the following knowledge and arrived at one embodiment of the present disclosure.

It is considered that the dislocation arrays of the threading edge dislocations are mainly classified into the following three types. A first type of dislocation array is a dislocation array transferred from a silicon carbide single crystal substrate to a silicon carbide layer to be formed by epitaxial growth. A second type of dislocation array is a dislocation array generated during epitaxial growth of the silicon carbide layer. The depth of each of a plurality of half loops included in the dislocation array is determined by the thickness of the silicon carbide layer at a time at which the half loops are generated. Accordingly, the plurality of half loops included in the dislocation array have different depths. Moreover, a direction in which each of the plurality of half loops is arranged (i.e., the longitudinal direction of the dislocation array) has a component in a step-flow growth direction (off direction). That is, the longitudinal direction of the dislocation array is not perpendicular to the off direction. A third type of dislocation array is a dislocation array generated after end of the epitaxial growth of the silicon carbide layer. This dislocation array is considered to be formed due to the basal plane dislocation in the silicon carbide layer being slid in a direction perpendicular to the off direction after the end of the epitaxial growth. Hence, the longitudinal direction of the dislocation array is perpendicular to the off direction. Moreover, the respective depths of the plurality of half loops included in the dislocation array are substantially the same.

Particularly, the inventors paid attention to suppression of generation of the third type of dislocation array. It is considered that the basal plane dislocation is slid in the direction perpendicular to the off direction to relax stress in the silicon carbide layer, thereby forming half loops in the silicon carbide layer. Moreover, it is considered that stress is generated in the silicon carbide layer mainly in a step of cooling the silicon carbide epitaxial substrate. Based on the above knowledge, the inventors have found that the stress in the silicon carbide epitaxial substrate can be relaxed to suppress generation of the third type of dislocation array by controlling a rate of cooling the silicon carbide epitaxial substrate in a below-described manner in the step of cooling the silicon carbide epitaxial substrate. Accordingly, the area density of the first dislocation array of the first half loops along the straight line perpendicular to the off direction can be reduced.

(2) In silicon carbide epitaxial substrate 100 according to (1), maximum diameter 111 may be not less than 150 mm.

(3) In silicon carbide epitaxial substrate 100 according to (1) or (2), off direction may be a <11-20> direction.

(4) In silicon carbide epitaxial substrate 100 according to (1) to (3), central region 53 may be provided with a second dislocation array 5 of second half loops 4 along a straight line inclined relative to the off direction. Each of second half loops 4 may include a pair of threading edge dislocations exposed at second main surface 30.

The area density of first dislocation array 2 may be lower than an area density of second dislocation array 5 in central region 53.

(5) In silicon carbide epitaxial substrate 100 according to (1) to (4), second main surface 30 may correspond to a plane inclined by not more than 4° relative to a (0001) plane.

(6) In silicon carbide epitaxial substrate 100 according to (1) to (4), second main surface 30 corresponds to a plane inclined by not more than 4° relative to a (000-1) plane.

(7) A silicon carbide epitaxial substrate 100 according to the present disclosure includes a silicon carbide single crystal substrate 10 and a silicon carbide layer 20. Silicon carbide single crystal substrate 10 has a first main surface 11. Silicon carbide layer 20 is on first main surface 11. Silicon carbide layer 20 includes a second main surface 30 opposite to a surface 14 in contact with silicon carbide single crystal substrate 10. Second main surface 30 corresponds to a plane inclined by not more than 4° relative to a (0001) plane in a <11-20> direction. Second main surface 30 has a maximum diameter 111 of not less than 150 mm. Second main surface 30 has an outer circumferential region 52 and a central region 53, outer circumferential region 52 being within 3 mm from an outer edge 54 of second main surface 30, central region 53 being surrounded by outer circumferential region 52. Central region 53 is provided with dislocation array 2 of half loops 1 along a straight line perpendicular to the <11-20> direction. Each of half loops 1 includes a pair of threading edge dislocations exposed at second main surface 30. An area density of dislocation array 2 at central region 53 is not more than 10/cm².

(8) A method for manufacturing a silicon carbide semiconductor device 300 according to the present disclosure includes the following steps. Silicon carbide epitaxial substrate 100 recited in any one of (1) to (7) is prepared. Silicon carbide epitaxial substrate 100 is processed.

### Details of Embodiment of Present Disclosure

The following describes one embodiment (hereinafter, referred to as “the present embodiment”) of the present disclosure more in detail. However, the present embodiment is not limited to these.

(Silicon Carbide Epitaxial Substrate)

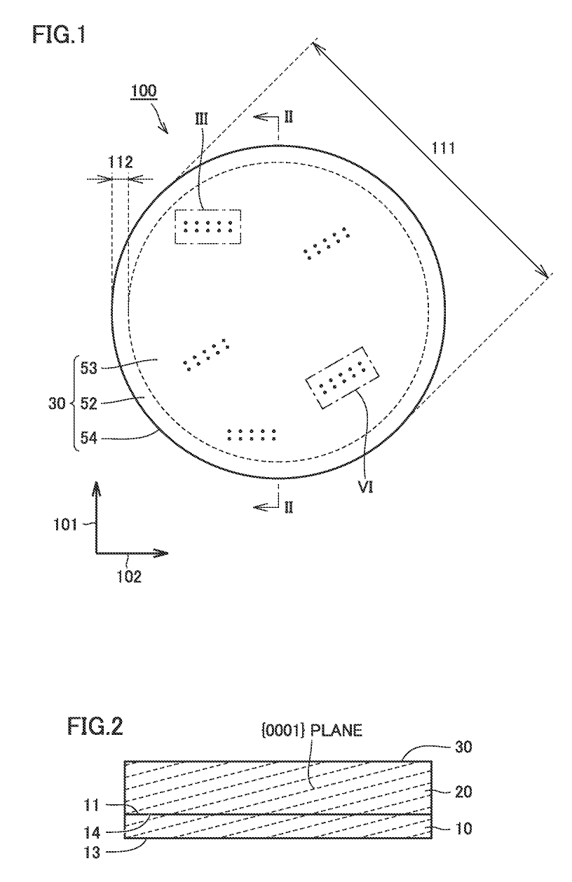

As shown in FIG. 1 and FIG. 2, a silicon carbide epitaxial substrate 100 according to the present embodiment has a silicon carbide single crystal substrate 10 and a silicon carbide layer 20. Silicon carbide single crystal substrate 10 includes a first main surface 11, and a third main surface 13 opposite to first main surface 11. Silicon carbide layer 20 includes: a fourth main surface 14 in contact with silicon carbide single crystal substrate 10; and a second main surface 30 opposite to fourth main surface 14. Silicon carbide epitaxial substrate 100 may have: a first flat (not shown) extending in a first direction 101; and a second flat (not shown) extending in a second direction 102. First direction 101 is a <11-20> direction, for example. Second direction 102 is a <1-100> direction, for example.

Silicon carbide single crystal substrate 10 (hereinafter, also simply referred to as “single crystal substrate”) is composed of a silicon carbide single crystal. The silicon carbide single crystal has a polytype of 4 H-SiC, for example. 4 H-SiC is more excellent than other polytypes in terms of electron mobility, dielectric strength, and the like. Silicon carbide single crystal substrate 10 includes an n type impurity such as nitrogen (N), for example. Silicon carbide single crystal substrate 10 has n type conductivity, for example. First main surface 11 corresponds to a plane inclined by not more than 4° relative to a {0001} plane, for example. When first main surface 11 is inclined relative to the {0001} plane, a direction in which the normal line of first main surface 11 is inclined is the <11-20> direction, for example.

As shown in FIG. 2, silicon carbide layer 20 is an epitaxial layer formed on silicon carbide single crystal substrate 10. Silicon carbide layer 20 is on first main surface 11. Silicon carbide layer 20 is in contact with first main surface 11. Silicon carbide layer 20 includes an n type impurity such as nitrogen, for example. Silicon carbide layer 20 has n type conductivity, for example. The concentration of the n type impurity in silicon carbide layer 20 may be lower than the concentration of the n type impurity in silicon carbide single crystal substrate 10. As shown in FIG. 1, second main surface 30 has a maximum diameter 111 (diameter) of not less than 100 mm. Maximum diameter 111 of silicon carbide epitaxial substrate 100 according to the present embodiment is 150 mm. Maximum diameter 111 may be not less than 150 mm, not less than 200 mm, or not less than 250 mm. The upper limit of maximum diameter 111 is not particularly limited. The upper limit of maximum diameter 111 may be 300 mm, for example.

Second main surface 30 corresponds to a plane inclined relative to a {0001} plane in an off direction. The off direction may be the <11-20> direction, the <1-100> direction, or a direction between the <11-20> direction and the <1-100> direction, for example. Specifically, the off direction may be a [11-20] direction, a [1-100] direction, or a direction between the [11-20] direction and the [1-100] direction, for example. Second main surface 30 may correspond to a plane inclined by not more than 4° relative to the (0001) plane. Second main surface 30 may correspond to a plane inclined by not more than 4° relative to the (000-1) plane. The inclination angle (off angle) relative to the {0001} plane may be not less than 1° or not less than 2°. The off angle may be not more than 3°.

As shown in FIG. 1, second main surface 30 has an outer circumferential region 52 and a central region 53 surrounded by outer circumferential region 52. Outer circumferential region 52 is a region within 3 mm from an outer edge 54 of second main surface 30. In other words, a distance 112 is 3 mm between outer edge 54 and a boundary between outer circumferential region 52 and central region 53 in a radial direction of second main surface 30.

(Dislocation Array of Half Loops Along Straight Line Perpendicular to Off Direction)

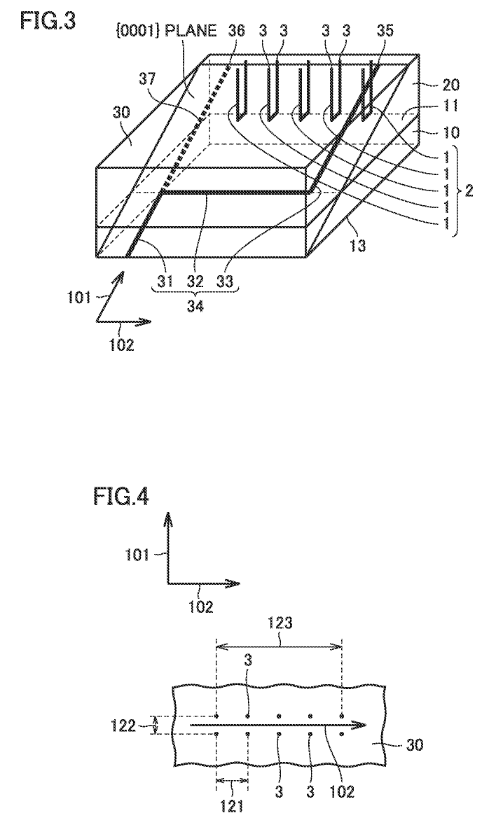

As shown in FIG. 1 and FIG. 3, central region 53 is provided with a first dislocation array 2 of first half loops 1 along a straight line perpendicular to the off direction. First dislocation array 2 includes the plurality of first half loops 1. When the off direction is first direction 101, a direction perpendicular to the off direction is second direction 102. Each of first half loops 1 includes a pair of threading edge dislocations exposed at second main surface 30. The area density of first dislocation array 2 in central region 53 is not more than 10/cm². Preferably, the area density of first dislocation array 2 in central region 53 is not more than 8/cm², more preferably, not more than 5/cm².

Next, the following describes a method for measuring the area density of the dislocation array.

First, central region 53 is etched by molten KOH (potassium hydroxide) to form etch pits in central region 53. The molten KOH has a temperature of 515° C., for example. The etching with the molten KOH is performed for 8 minutes, for example. Next, the etch pits formed in central region 53 are observed using an optical microscope. Central region 53 is divided into square regions of 1 cm×1 cm in the form of a lattice, for example. The area densities of the dislocation arrays are measured in all the square regions. The expression “the area density of first dislocation array 2 in central region 53 is not more than 10/cm²” is intended to indicate that the area density of first dislocation array 2 in each of the square regions is not more than 10/cm². It should be noted that since a portion of central region 53 around the outer circumference has a rounded shape, the portion cannot be divided into a square region. For the calculation of the area density of the dislocation array, the area density of first dislocation array 2 in such a region that cannot be divided into a square region is not taken into consideration.

As shown in FIG. 3, first half loop 1 has a substantially U-like shape. First half loop 1 has a curved portion provided in silicon carbide layer 20. End portions 3 of the pair of threading edge dislocations are exposed at second main surface 30. The curved portion of first half loop 1 may be a dislocation other than the threading edge dislocation. Silicon carbide epitaxial substrate 100 includes a basal plane dislocation 34. Basal plane dislocation 34 includes a first portion 31, a second portion 32, and a third portion 33. First portion 31 is a basal plane dislocation existing in silicon carbide single crystal substrate 10. Second portion 32 is an interface dislocation existing at an interface between silicon carbide single crystal substrate 10 and silicon carbide layer 20. Third portion 33 is a basal plane dislocation existing in silicon carbide layer 20. First portion 31 is continuous to second portion 32. Second portion 32 is continuous to third portion 33. First portion 31 is exposed at third main surface 13 of silicon carbide single crystal substrate 10. Third portion 33 is exposed at second main surface 30 of silicon carbide layer 20. In other words, basal plane dislocation 34 has one end portion 35 exposed at second main surface 30, and has the other end portion exposed at third main surface 13.

As shown in FIG. 3, first dislocation array 2 may be located between one end portion 35 of basal plane dislocation 34 and a point 36 at which a hypothetical line 37 is exposed on second main surface 30. Hypothetical line 37 is obtained by extending first portion 31 to the silicon carbide layer 20 side along a direction in which first portion 31 extends. In other words, each of the plurality of first half loops 1 included in first dislocation array 2 may be located between point 36 and end portion 35. That is, when viewed in the direction perpendicular to second main surface 30, first dislocation array 2 may be located between hypothetical line 37 and third portion 33.

As shown in FIG. 4, a length 123 of first dislocation array 2 in second direction 102 is not less than 0.1 mm and not more than 50 mm, for example. A distance 122 between one end portion 3 and the other end portion 3 in first direction 101 is not less than 1 μm and not more than 10 μm, for example. A distance 121 between two adjacent first half loops 1 in second direction 102 is not less than 1 μm and not more than 100 μm, for example. Distance 121 may be longer than distance 122. Two end portions 3 may be located along first direction 101. Intervals between two adjacent first half loops may be the same or different. When viewed in the direction perpendicular to second main surface 30, each of the plurality of half loops 1 overlaps with a straight line parallel to second direction 102. The longitudinal direction of first dislocation array 2 is second direction 102. The longitudinal direction of first dislocation array 2 may be parallel to a direction in which the interface dislocation extends.

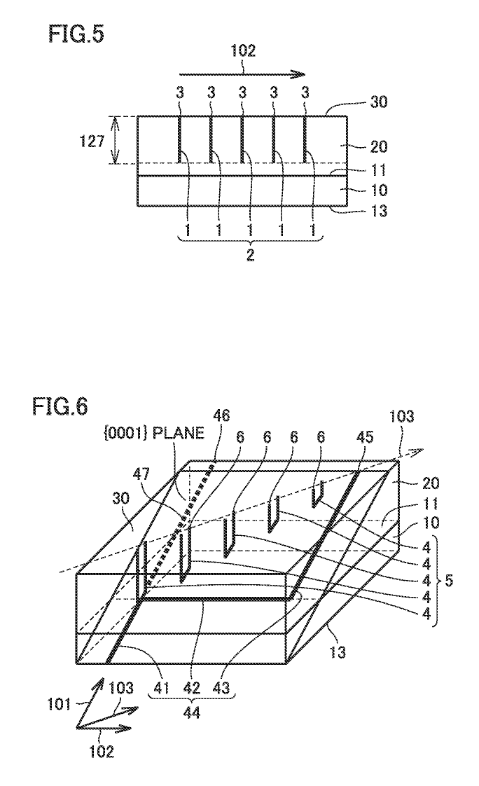

As shown in FIG. 5, in the direction perpendicular to second main surface 30, each of the plurality of half loops 1 may have substantially the same depth. The depth of first half loop 1 refers to the length of the half loop in the direction perpendicular to second main surface 30. The depth of first half loop 1 may be less than the thickness of silicon carbide layer 20. First half loop 1 may be spaced away from silicon carbide single crystal substrate 10.

(Dislocation Array of Half Loops Along Straight Line Inclined Relative to Off Direction)

As shown in FIG. 1 and FIG. 6, central region 53 may be provided with a second dislocation array 5 of second half loops 4 along a straight line inclined relative to the off direction. Second dislocation array 5 includes the plurality of second half loops 4. Second half loops 4 are along a third direction 103 parallel to a straight line inclined relative to both first direction 101 and second direction 102. Second half loop 4 includes a pair of threading edge dislocations exposed at second main surface 30. In central region 53, the area density of first dislocation array 2 may be lower than the area density of second dislocation array 5. The area density of second dislocation array 5 in central region 53 may be higher than 10/cm². A multiplicity of first dislocation arrays 2 tend to exist near outer circumferential region 52, whereas a multiplicity of second dislocation arrays 5 tend to exist near the center of central region 53.

As shown in FIG. 6, each of second half loops 4 has a substantially U-like shape. Second half loop 4 has a curved portion provided in silicon carbide layer 20, and end portions 6 of the pair of threading edge dislocations are exposed at second main surface 30. The curved portion of second half loop 4 may be a dislocation other than the threading edge dislocation. Silicon carbide epitaxial substrate 100 includes a basal plane dislocation 44. Basal plane dislocation 44 includes a fourth portion 41, a fifth portion 42, and a sixth portion 43. Fourth portion 41 is a basal plane dislocation existing in silicon carbide single crystal substrate 10. Fifth portion 42 is an interface dislocation existing at the interface between silicon carbide single crystal substrate 10 and silicon carbide layer 20. Sixth portion 43 is a basal plane dislocation existing in silicon carbide layer 20. Fourth portion 41 is continuous to fifth portion 42. Fifth portion 42 is continuous to sixth portion 43. Fourth portion 41 is exposed at third main surface 13 of silicon carbide single crystal substrate 10. Sixth portion 43 is exposed at second main surface 30 of silicon carbide layer 20. In other words, basal plane dislocation 44 has one end portion 45 exposed at second main surface 30, and has the other end portion exposed at third main surface 13. When viewed in the direction perpendicular to second main surface 30, second dislocation array 5 may be located between sixth portion 43 and a hypothetical line 47, which is obtained by extending fourth portion 41 to the silicon carbide layer 20 side along the direction in which fourth portion 41 extends. In other words, second dislocation array 5 may be located between one end portion 45 of basal plane dislocation 44 and a point 46 at which hypothetical line 47 is exposed on second main surface 30.

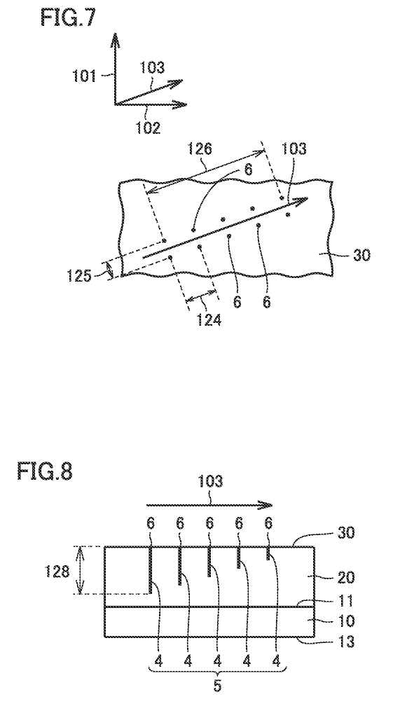

As shown in FIG. 7, a length 126 of second dislocation array 5 in third direction 103 is not less than 0.1 mm and not more than 50 mm, for example. In the direction perpendicular to third direction 103, a distance 125 between one end portion 6 and the other end portion 6 is not less than 1 μm and not more than 10 μm, for example. A distance 124 between two adjacent second half loops 4 in third direction 103 is not less than 1 μm and not more than 100 μm, for example. Distance 124 may be longer than distance 125. Two end portions 6 may be located on a straight line perpendicular to third direction 103. When viewed in the direction perpendicular to second main surface 30, each of the plurality of second half loops 4 overlaps with a straight line parallel to third direction 103. Intervals between two adjacent second half loops may be the same or different.

As shown in FIG. 8, in the direction perpendicular to second main surface 30, the plurality of second half loops 4 may have different depths. The depth of second half loop 4 refers to the length of the half loop in the direction perpendicular to second main surface 30. Specifically, the depths of second half loops 4 may become smaller in the off direction. In other words, when viewed in the direction perpendicular to second main surface 30, the depth of second half loop 4 near fourth portion 41 is larger than the depth of second half loop 4 near sixth portion 43. The depth of second half loop 4 may be less than the thickness of silicon carbide layer 20. Second half loop 4 may be spaced away from silicon carbide single crystal substrate 10.

(Film Forming Apparatus)

Next, the following describes a configuration of a manufacturing apparatus 200 used in the method for manufacturing silicon carbide epitaxial substrate 100 according to the present embodiment.

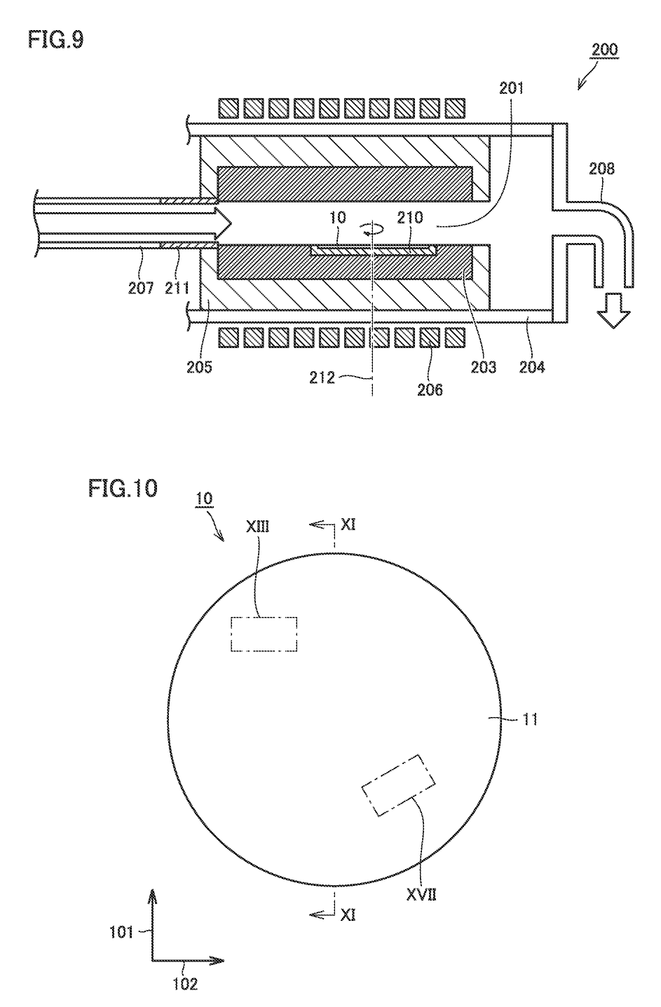

As shown in FIG. 9, manufacturing apparatus 200 is a hot wall type CVD (Chemical Vapor Deposition) apparatus, for example. Manufacturing apparatus 200 mainly has heating elements 203, a quartz tube 204, a heat insulator 205, an induction heating coil 206, and a preheating structure 211. A hollow space surrounded by heating elements 203 is a reaction chamber 201. In reaction chamber 201, a susceptor plate 210 configured to hold silicon carbide single crystal substrate 10 is provided. Susceptor plate 210 is rotatable. Silicon carbide single crystal substrate 10 is disposed on susceptor plate 210 with first main surface 11 facing upward.

Heating element 203 is composed of graphite, for example. Induction heating coil 206 is wound around the outer circumference of quartz tube 204. Next, a predetermined alternating current is supplied to induction heating coil 206, thereby inductively heating elements 203. Accordingly, reaction chamber 201 is heated.

Manufacturing apparatus 200 further has a gas inlet 207 and a gas outlet 208. Gas outlet 208 is connected to a gas exhaustion pump (not shown). An arrow in FIG. 9 represents a flow of gas. Carrier gas, source material gas, and doping gas are introduced from gas inlet 207 into reaction chamber 201, and are exhausted from gas outlet 208. A pressure in reaction chamber 201 may be adjusted in accordance with a balance between an amount of supply of the gases and an amount of exhaustion of the gases.

Normally, susceptor plate 210 and single crystal substrate 10 are disposed at substantially the center of reaction chamber 201 in the axial direction. As shown in FIG. 9, in the present disclosure, susceptor plate 210 and single crystal substrate 10 may be disposed at a downstream side relative to the center of reaction chamber 201, i.e., at the gas outlet 208 side in order to sufficiently promote a reaction of decomposing the source material gas until the source material gas reaches single crystal substrate 10. Accordingly, it is expected to attain a uniform distribution of C/Si ratio in the plane of single crystal substrate 10.

Ammonia gas, which serves as the dopant gas, is desirably thermally decomposed in advance by sufficiently heating before being supplied to reaction chamber 201. Accordingly, in silicon carbide layer 20, it can be expected to improve in-plane uniformity of a nitrogen (dopant) density. As shown in FIG. 9, preheating structure 211 may be provided at the upstream side in reaction chamber 201. In preheating structure 211, the ammonia gas can be heated in advance. Preheating structure 211 includes a chamber heated at not less than 1300° C., for example. When passing through the inside of preheating structure 211, the ammonia gas is thermally decomposed sufficiently and then is supplied to reaction chamber 201. With such a configuration, the ammonia gas can be thermally decomposed without causing a large turbulence in the flow of the gas.

(Method for Manufacturing Silicon Carbide Epitaxial Substrate)

Next, the following describes a method for manufacturing the silicon carbide epitaxial substrate according to the present embodiment.

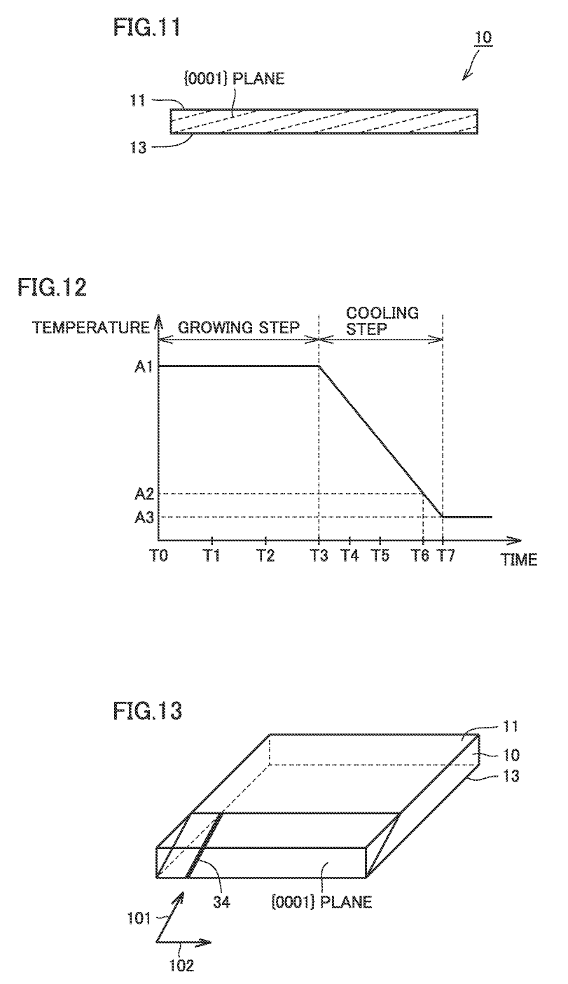

First, for example, a silicon carbide single crystal of polytype 4H is produced by a sublimation method. Next, the silicon carbide single crystal is sliced using, for example, a wire saw, thereby preparing silicon carbide single crystal substrate 10 (see FIG. 10 and FIG. 11). Silicon carbide single crystal substrate 10 has first main surface 11 and third main surface 13 opposite to first main surface 11. As shown in FIG. 11, first main surface 11 corresponds to a plane inclined relative to the {0001} plane in the off direction.

Specifically, first main surface 11 corresponds to a plane inclined by not more than 4° relative to the {0001} plane, for example. First main surface 11 may correspond to a plane inclined by not more than 4° relative to the (0001) plane or may correspond to a plane inclined by not more than 4° relative to the (000-1) plane. An inclination angle (off angle) relative to the {0001} plane may be not less than 1° and not less than 2°. The off angle may be not more than 3°. The off direction may be the <11-20> direction, the <1-100> direction, or the direction between the <11-20> direction and the <1-100> direction, for example.

Next, silicon carbide single crystal substrate 10 is placed in manufacturing apparatus 200 mentioned above. Specifically, silicon carbide single crystal substrate 10 is placed in a recess of susceptor plate 210 to expose first main surface 11 from susceptor plate 210. Next, silicon carbide layer 20 is formed on silicon carbide single crystal substrate 10 by epitaxial growth. For example, after the pressure of reaction chamber 201 is reduced from the atmospheric pressure to about 1×10⁻⁶ Pa, silicon carbide single crystal substrate 10 starts to be heated. During the heating, hydrogen (H₂) gas, which serves as the carrier gas, is introduced into reaction chamber 201.

After the temperature in reaction chamber 201 reaches about 1600° C., the source material gas and the doping gas are introduced into reaction chamber 201, for example. The source material gas includes a Si source gas and a C source gas. As the Si source gas, silane (SiH₄) gas may be used, for example. As the C source gas, propane (C₃H₈) gas can be used, for example. The flow rate of the silane gas and the flow rate of the propane gas are 46 sccm and 14 sccm, for example. A volume ratio of the silane gas to the hydrogen is 0.04%, for example. A C/Si ratio of the source material gas is 0.9, for example.

As the doping gas, ammonia (NH₃) gas is used, for example. The ammonia gas is more likely to be thermally decomposed than nitrogen gas having a triple bond. By using the ammonia gas, the in-plane uniformity of the carrier concentration can be expected to be improved. A ratio of the concentration of the ammonia gas to the concentration of the hydrogen gas is 1 ppm, for example. The ammonia gas is desirably thermally decomposed in advance by preheating structure 211 before being introduced into reaction chamber 201. By preheating structure 211, the ammonia gas is heated at not less than 1300° C., for example.

The carrier gas, the source material gas, and the doping gas are introduced into reaction chamber 201 with silicon carbide single crystal substrate 10 being heated at about 1600° C., thereby forming silicon carbide layer 20 on silicon carbide single crystal substrate 10 by epitaxial growth. During the epitaxial growth of silicon carbide layer 20, susceptor plate 210 is rotated around a rotation axis 212 (see FIG. 9). The average rotation speed of susceptor plate 210 is 20 rpm, for example. In this way, silicon carbide layer 20 is formed on silicon carbide single crystal substrate 10 by epitaxial growth.

As shown in FIG. 12, in the step of growing silicon carbide layer 20, the temperature of silicon carbide single crystal substrate 10 is maintained at a first temperature (A1) during a period of a zeroth time (T0) to a third time (T3). The first temperature (A1) is 1600° C., for example. The zeroth time (T0) is a time at which the source material gas and the doping gas start to be introduced into reaction chamber 201. At the zeroth time (T0), silicon carbide layer 20 substantially starts to be formed on silicon carbide single crystal substrate 10. The third time (T3) is a time at which the introduction of the source material gas and the doping gas into reaction chamber 201 is ended. At the third time (T3), the formation of silicon carbide layer 20 on silicon carbide single crystal substrate 10 is substantially ended. Preferably, in the step of growing silicon carbide layer 20, the temperature of silicon carbide single crystal substrate 10 in the in-plane direction is maintained uniformly. Specifically, a difference between the maximum temperature and the minimum temperature is maintained at not more than 10° C. in first main surface 11 of silicon carbide single crystal substrate 10 during the period of the zeroth time (T0) to the third time (T3).

Next, the following fully describes a step of growing a portion of silicon carbide layer 20 on a region XIII of silicon carbide single crystal substrate 10.

As shown in FIG. 10 and FIG. 13, at the zeroth time (T0), a basal plane dislocation 34 extends on the {0001} plane in silicon carbide single crystal substrate 10 at certain region XIII. Basal plane dislocation 34 has one end portion exposed at first main surface 11 and has the other end portion exposed at third main surface 13. Basal plane dislocation 34 extends along first direction 101, which is the off direction.

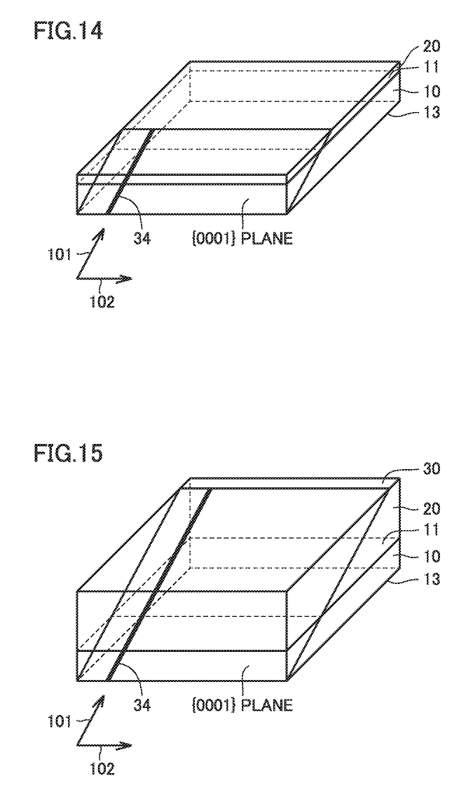

As shown in FIG. 14, at the first time (T1), a portion of silicon carbide layer 20 is formed on silicon carbide single crystal substrate 10. Basal plane dislocation 34 is propagated from silicon carbide single crystal substrate 10 to silicon carbide layer 20. Basal plane dislocation 34 extends in silicon carbide layer 20 along first direction 101. The one end portion of basal plane dislocation 34 is exposed at the surface of silicon carbide layer 20 and the other end portion thereof is exposed at third main surface 13.

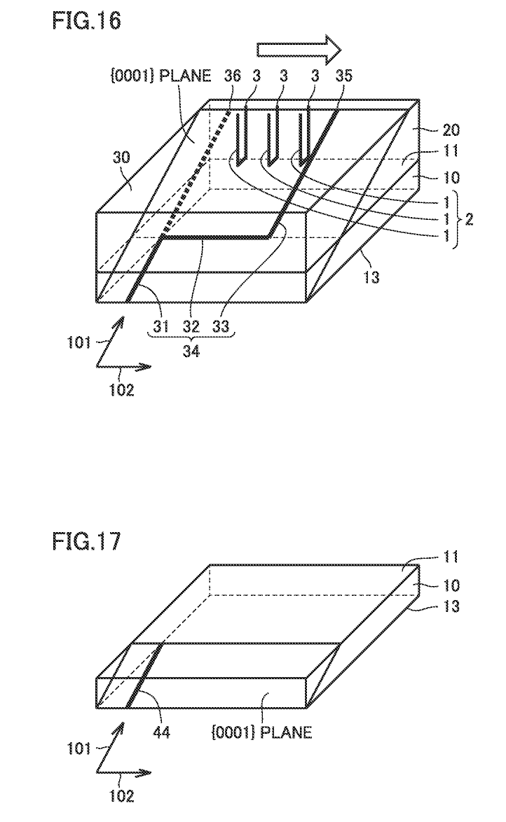

As shown in FIG. 15, basal plane dislocation 34 extends further in silicon carbide layer 20 as silicon carbide layer 20 is grown. At the third time (T3) subsequent to the first time (T1), the one end portion of basal plane dislocation 34 is exposed at second main surface 30 of silicon carbide layer 20 and the other end portion thereof is exposed at third main surface 13 of silicon carbide single crystal substrate 10. Accordingly, the formation of silicon carbide layer 20 is substantially completed.

Next, the following describes a step of cooling silicon carbide epitaxial substrate 100.

As shown in FIG. 12, the cooling step is performed after the end of the growing step. A period of the third time (T3) to a seventh time (T7) corresponds to the cooling step. In the cooling step, silicon carbide epitaxial substrate 100 including silicon carbide single crystal substrate 10 and silicon carbide layer 20 is cooled. For example, during the period of the third time (T3) to the sixth time (T6), the temperature of silicon carbide epitaxial substrate 100 is decreased from the first temperature (A1) to the second temperature (A2). The period of the third time (T3) to the sixth time (T6) is 60 minutes, for example. The first temperature (A1) is 1600° C., and the second temperature (A2) is 100° C., for example. Thus, the rate of cooling silicon carbide epitaxial substrate 100 is (1600-100°) C/1 h=1500° C./h, for example. The rate of cooling from the first temperature (A1) to the second temperature (A2) may be not more than 1500° C./h, not more than 1300° C./h, or not more than 1000° C./h.

As shown in FIG. 16, in the cooling step, first dislocation array 2 including first half loops 1 may be formed in silicon carbide layer 20. It is considered that first dislocation array 2 is generated due to third portion 33 of the basal plane dislocation in silicon carbide layer 20 being slid in second direction 102 perpendicular to the off direction. Basal plane dislocation 34 (see FIG. 15) in the growing step is changed into a basal plane dislocation 34 (FIG. 16) including first portion 31, second portion 32, and third portion 33 in the cooling step, and forms the plurality of first half loops 1. In other words, first half loops 1 thus formed are originated from basal plane dislocation 34.

Preferably, in the step of cooling silicon carbide epitaxial substrate 100, the temperature of silicon carbide epitaxial substrate 100 in the in-plane direction is maintained uniformly. Specifically, during the period of the third time (T3) to the sixth time (T6), a difference between the maximum temperature and the minimum temperature in second main surface 30 of silicon carbide epitaxial substrate 100 is maintained at not more than 10° C. By decreasing the rate of cooling silicon carbide epitaxial substrate 100 in the cooling step as described above, the uniformity of the temperature of silicon carbide epitaxial substrate 100 in the in-plane direction can be improved. As a result, stress is relaxed in silicon carbide epitaxial substrate 100, thereby suppressing generation of first dislocation array 2 of first half loops 1 along the straight line perpendicular to the off direction.

Next, during a period of the fifth time (T5) to the sixth time (T6), the temperature of silicon carbide epitaxial substrate 100 is decreased from the second temperature (A2) to the third temperature (A3). The third temperature (A3) is a room temperature, for example. After the temperature of silicon carbide epitaxial substrate 100 becomes around the room temperature, silicon carbide epitaxial substrate 100 is taken out from reaction chamber 201. In this way, silicon carbide epitaxial substrate 100 is completed (see FIG. 1).

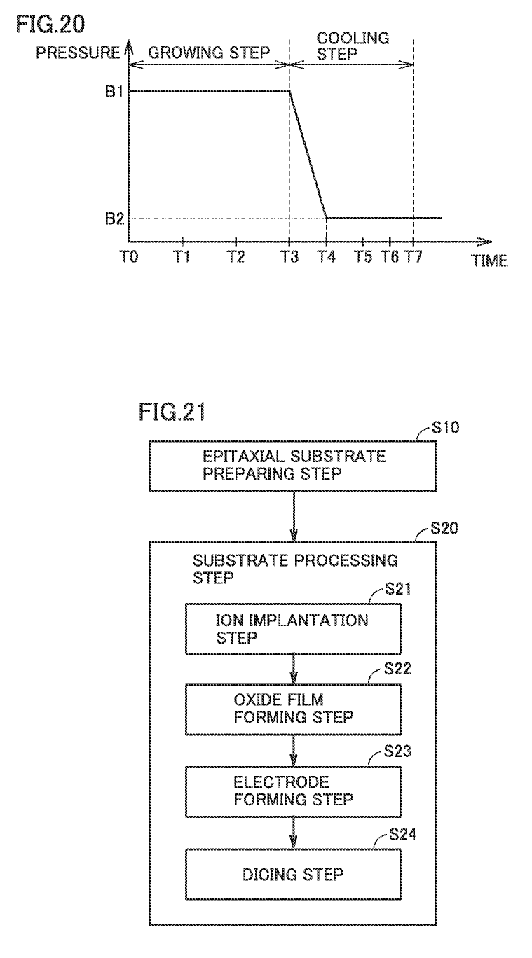

As shown in FIG. 20, a pressure in reaction chamber 201 may be reduced in the cooling step. For example, a pressure in reaction chamber 201 is decreased from a first pressure (B1) to a second pressure (B2) during the period of the third time (T3) to the fourth time (T4). The first pressure (B1) is 100 mbar (10 kPa), and the second pressure (B2) is 10 mbar (1 kPa), for example. The period of the third time (T3) to the fourth time (T4) is 10 minutes, for example. That is, the rate of reducing the pressure in reaction chamber 201 is (10-1) kPa/10 min=0.9 kPa/min. The rate of reducing the pressure in reaction chamber 201 may be not less than 0.9 kPa/min, not less than 1.2 kPa/min, or not less than 1.5 kPa/min. By rapidly reducing the pressure of reaction chamber 201 in the cooling step, the inside of reaction chamber 201 is thermally insulated from outside, thus reducing the rate of cooling silicon carbide epitaxial substrate 100.

The pressure in reaction chamber 201 can be reduced by reducing the flow rate of the carrier gas, for example. For example, the flow rate of the carrier gas in the growing step may be 120 slm, and the flow rate of the carrier gas in the cooling step may be 12 slm. In the growing step, the carrier gas, the dopant gas, and the source material gas are supplied to reaction chamber 201. In the cooling step, only the carrier gas may be supplied to reaction chamber 201. The flow rate of the carrier gas may be reduced immediately after the end of the growing step, or may be reduced after maintaining, the flow rate in the growing step, for a certain period in the cooling step.

Next, the following fully describes the step of growing a portion of silicon carbide layer 20 on a certain region XVI of silicon carbide single crystal substrate 10.

As shown in FIG. 10 and FIG. 17, at the zeroth time (T0), basal plane dislocation 44 existing on the {0001} plane may exist in a certain region XVII in silicon carbide single crystal substrate 10. Basal plane dislocation 44 has one end portion exposed at first main surface 11 and has the other end portion exposed at third main surface 13. The basal plane dislocation extends along first direction 101, which is the off direction.

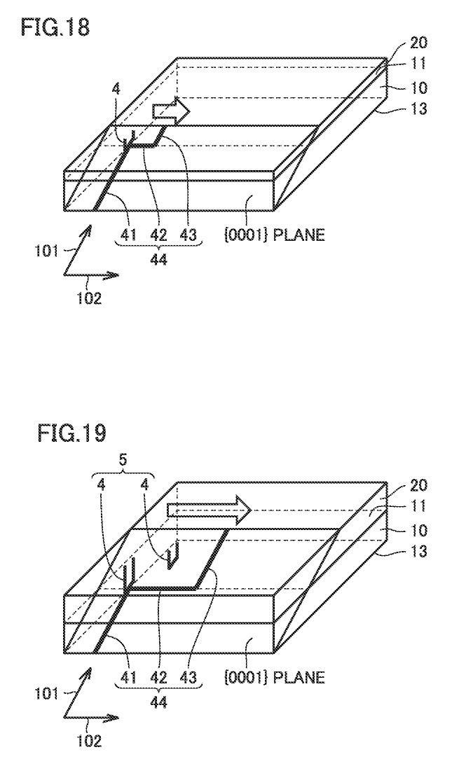

As shown in FIG. 18, at the first time (T1), second half loops 4 are originated from basal plane dislocation 44. The two end portions of second half loop 4 are exposed at the surface of silicon carbide layer 20. Sixth portion 43 of the basal plane dislocation extending in silicon carbide layer 20 is shifted to the second direction (a direction of arrow in FIG. 18). As a result, basal plane dislocation 44 is transformed into: fourth portion 41 located in silicon carbide single crystal substrate 10; fifth portion 42 located at the interface between silicon carbide single crystal substrate 10 and silicon carbide layer 20 and extending in the second direction; and sixth portion 43 located in silicon carbide layer 20. Accordingly, second half loop 4 is generated. The one end portion of basal plane dislocation 44 is exposed at the surface of silicon carbide layer 20, and the other end portion thereof is exposed at third main surface 13.

As shown in FIG. 19, at the second time (T2), another second half loop 4 is originated from basal plane dislocation 44. The other second half loop 4 is generated at the first direction 101 side and the second direction 102 side relative to the previously generated second half loop 4. The depth of the previously generated second half loop 4 is larger than the depth of the later generated second half loop 4. At the first time (T1), sixth portion 43 of the basal plane dislocation existing in silicon carbide layer 20 is further shifted to the second direction (a direction of arrow in FIG. 19). Sixth portion 43 is exposed at the surface of silicon carbide layer 20. In the manner described above, the plurality of second half loops 4 are formed along the straight line inclined relative to the off direction. Along with passage of time, the number of second half loops 4 is increased. At the third time (T3), second dislocation array 5 of second half loops 4 along the straight line inclined relative to the off direction is formed (see FIG. 6). As described above, second dislocation array 5 is formed in the step of forming the silicon carbide layer (i.e., the growing step). In other words, in the step of cooling silicon carbide epitaxial substrate 100, it is considered that second dislocation array 5 is not generated or not eliminated.

(Method for Manufacturing Silicon Carbide Semiconductor Device)

The following describes a method for manufacturing a silicon carbide semiconductor device 300 according to the present embodiment.

The method for manufacturing the silicon carbide semiconductor device according to the present embodiment mainly includes an epitaxial substrate preparing step (S10: FIG. 21) and a substrate processing step (S20: FIG. 21).

First, the epitaxial substrate preparing step (S10: FIG. 21) is performed. Specifically, silicon carbide epitaxial substrate 100 is prepared by the method for manufacturing the silicon carbide epitaxial substrate as described above (see FIG. 1). The epitaxial substrate preparing step (S10: FIG. 21) may include a step of forming a buffer layer 21 on silicon carbide single crystal substrate 10.

Next, the substrate processing step (S20: FIG. 21) is performed. Specifically, by processing the silicon carbide epitaxial substrate, the silicon carbide semiconductor device is manufactured. The term “process” includes various types of processes such as ion implantation, heat treatment, etching, oxide film formation, electrode formation, and dicing. That is, the substrate processing step may include at least one of the processes such as the ion implantation, the heat treatment, the etching, the oxide film formation, the electrode formation, and the dicing.

The following describes a method for manufacturing a MOSFET (Metal Oxide Semiconductor Field Effect Transistor) as an example of the silicon carbide semiconductor device. The substrate processing step (S20: FIG. 21) includes an ion implantation step (S21: FIG. 21), an oxide film forming step (S22: FIG. 21), an electrode forming step (S23: FIG. 21), and a dicing step (S24: FIG. 21).

First, the ion implantation step (S21: FIG. 21) is performed. For example, a p type impurity such as aluminum (Al) is implanted into second main surface 30 on which a mask (not shown) provided with an opening is formed. Accordingly, a body region 132 having p type conductivity is formed. Next, an n type impurity such as phosphorus (P) is implanted into a predetermined location in body region 132, for example. Accordingly, a source region 133 having n type conductivity is formed. Next, a p type impurity such as aluminum is implanted into a predetermined location in source region 133. Accordingly, a contact region 134 having p type conductivity is formed (see FIG. 22).

A portion of silicon carbide layer 20 other than body region 132, source region 133, and contact region 134 serves as a drift region 131. Source region 133 is separated from drift region 131 by body region 132. The ion implantation may be performed by heating silicon carbide epitaxial substrate 100 at about not less than 300° C. and not more than 600° C. After the ion implantation, silicon carbide epitaxial substrate 100 is subjected to activation annealing. Due to the activation annealing, the impurities implanted in silicon carbide layer 20 are activated, thus generating carriers in each region. An atmosphere for the activation annealing may be an argon (Ar) atmosphere, for example. The temperature of the activation annealing may be about 1800° C., for example. The time of the activation annealing may be about 30 minutes, for example.

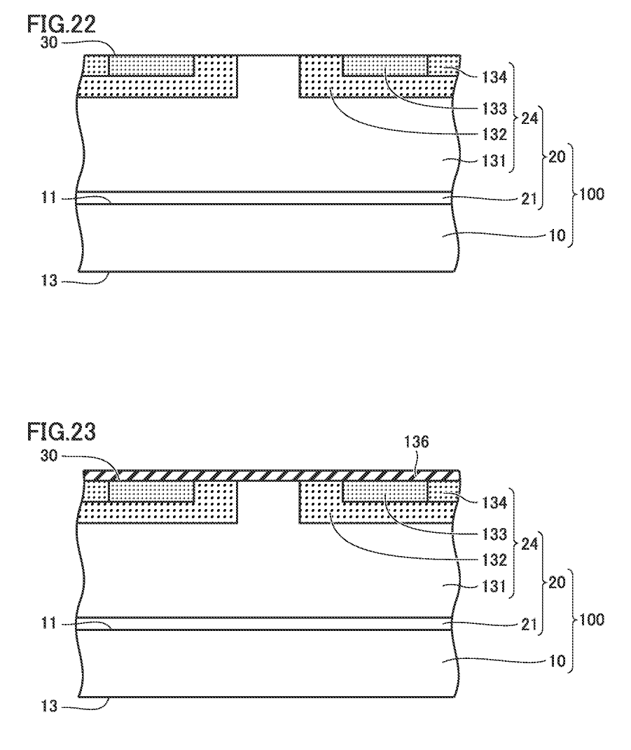

Next, an oxide film forming step (S22: FIG. 21) is performed. For example, silicon carbide epitaxial substrate 100 is heated in an atmosphere including oxygen, thereby forming an oxide film 136 on second main surface 30 (see FIG. 23). Oxide film 136 is composed of silicon dioxide (SiO₂) or the like, for example. Oxide film 136 functions as a gate insulating film. The temperature of the thermal oxidation treatment may be, for example, about 1300° C. The time of the thermal oxidation treatment may be, for example, about 30 minutes.

After forming oxide film 136, heat treatment may be further performed in a nitrogen atmosphere. For example, the heat treatment may be performed at about 1100° C. for about 1 hour in an atmosphere such as nitrogen monoxide (NO) or nitrous oxide (N₂O). Then, heat treatment may be further performed in an argon atmosphere. For example, the heat treatment may be performed in the argon atmosphere at about 1100° C. to 1500° C. for about 1 hour.

Next, the electrode forming step (S23: FIG. 21) is performed. A first electrode 141 is formed on oxide film 136. First electrode 141 functions as a gate electrode. First electrode 141 is formed by CVD, for example. First electrode 141 contains an impurity and is composed of polysilicon having conductivity or the like, for example. First electrode 141 is formed at a location facing source region 133 and body region 132.

Next, an interlayer insulating film 137 is formed to cover first electrode 141. Interlayer insulating film 137 is formed by CVD, for example. Interlayer insulating film 137 is composed of silicon dioxide or the like, for example. Interlayer insulating film 137 is formed in contact with first electrode 141 and oxide film 136. Next, oxide film 136 and interlayer insulating film 137 at a predetermined location are removed by etching. Accordingly, source region 133 and contact region 134 are exposed through oxide film 136.

For example, a second electrode 142 is formed at the exposed portion by sputtering. Second electrode 142 functions as a source electrode. Second electrode 142 is composed of titanium, aluminum, silicon, or the like, for example. After forming second electrode 142, second electrode 142 and silicon carbide epitaxial substrate 100 are heated at a temperature of about 900° C. to 1100° C., for example. Accordingly, second electrode 142 and silicon carbide epitaxial substrate 100 are brought into ohmic contact with each other. Next, an interconnection layer 138 is formed in contact with second electrode 142. Interconnection layer 138 is composed of a material including aluminum, for example.

Next, third electrode 143 is formed on third main surface 13. Third electrode 143 functions as a drain electrode. Third electrode 143 is composed of an alloy (for example, NiSi or the like) including nickel and silicon, for example.

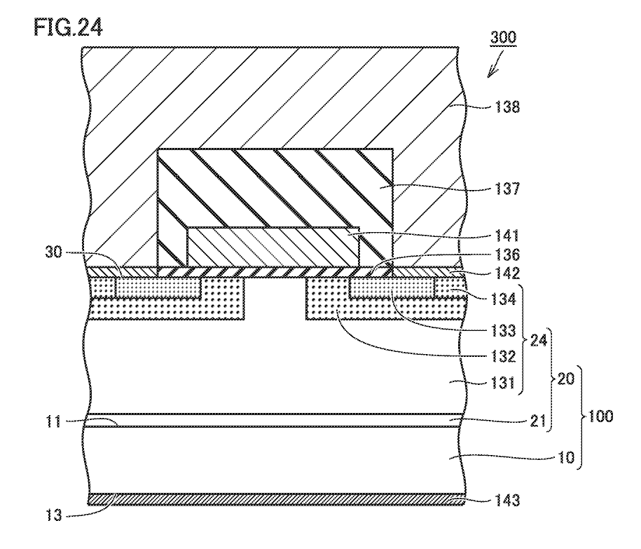

Next, the dicing step (S24: FIG. 21) is performed. For example, silicon carbide epitaxial substrate 100 is diced along a dicing line, thereby dividing silicon carbide epitaxial substrate 100 into a plurality of semiconductor chips. In this way, silicon carbide semiconductor device 300 is manufactured (see FIG. 24).

In the description above, the method for manufacturing the silicon carbide semiconductor device according to the present disclosure has been described with regard to the MOSFET as an example; however, the manufacturing method according to the present disclosure is not limited to this. The manufacturing method according to the present disclosure is applicable to various types of silicon carbide semiconductor devices such as an IGBT (Insulated Gate Bipolar Transistor), an SBD (Schottky Barrier Diode), a thyristor, a GTO (Gate Turn Off thyristor), and a PiN diode.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first half loop (half loop); 2: first dislocation array (dislocation array); 3, 6, 35, 45: end portion; 4: second half loop; 5: second dislocation array; 10: silicon carbide single crystal substrate; 11: first main surface; 13: third main surface; 14: fourth main surface (plane); 20: silicon carbide layer; 21: buffer layer; 30: second main surface; 31: first portion; 32: second portion; 33: third portion; 34, 44: basal plane dislocation; 37, 47: imaginary line; 41: fourth portion; 42: fifth portion; 43: sixth portion; 52: outer circumferential region; 53: central region; 54: outer edge; 100: silicon carbide epitaxial substrate; 101: first direction; 102: second direction; 103: third direction; 111: maximum diameter; 131: drift region; 132: body region; 133: source region; 134: contact region; 136: oxide film; 137: interlayer insulating film; 138: interconnection layer; 141: first electrode; 142: second electrode; 143: third electrode; 200: manufacturing apparatus; 201: reaction chamber; 203: heating element; 204: quartz tube; 205: heat insulator; 206: induction heating coil; 207: gas inlet; 208: gas outlet; 210: susceptor plate; 211: preheating structure; 212: rotation axis; 300: silicon carbide semiconductor device.

1. A silicon carbide epitaxial substrate comprising:
a silicon carbide single crystal substrate having a first main surface; and
a silicon carbide layer on the first main surface,
the silicon carbide layer including a second main surface opposite to a surface in contact with the silicon carbide single crystal substrate,
the second main surface corresponding to a plane inclined relative to a {0001} plane in an off direction,
the second main surface having a maximum diameter of not less than 100 mm,
the second main surface having an outer circumferential region and a central region, the outer circumferential region being within 3 mm from an outer edge of the second main surface, the central region being surrounded by the outer circumferential region,
the central region being provided with a first dislocation array of first half loops along a straight line perpendicular to the off direction,
each of the first half loops including a pair of threading edge dislocations exposed at the second main surface,
an area density of the first dislocation array at the central region being not more than 10/cm²,
the central region being provided with a second dislocation array of second half loops along a straight line inclined relative to the off direction,
each of the second half loops including a pair of threading edge dislocations exposed at the second main surface, and
the area density of the first dislocation array being lower than an area density of the second dislocation array in the central region.

2. The silicon carbide epitaxial substrate according to claim 1, wherein the maximum diameter is not less than 150 mm.

3. The silicon carbide epitaxial substrate according to claim 1, wherein the off direction is a <11-20> direction.

4. (canceled)

5. The silicon carbide epitaxial substrate according to claim 1, wherein the second main surface corresponds to a plane inclined by not more than 4° relative to a (0001) plane.

6. The silicon carbide epitaxial substrate according to claim 1, wherein the second main surface corresponds to a plane inclined by not more than 4° relative to a (000-1) plane.

7. (canceled)

8. A method for manufacturing a silicon carbide semiconductor device, the method comprising:
preparing the silicon carbide epitaxial substrate recited in claim 1; and
processing the silicon carbide epitaxial substrate.
